(19) United States
(12) Patent Application Publication
(10) Pub. No.: US 2024/0404438 A1
(43) Pub. Date: Dec. 5, 2024

(54) SUBSTRATE, SUBSTRATE INSPECTION METHOD, AND DISPLAY DEVICE MANUFACTURING METHOD

(71) Applicant: Japan Display Inc., Tokyo (JP)

(72) Inventor: Teruaki UCHIYAMA, Tokyo (JP)

(73) Assignee: Japan Display Inc., Tokyo (JP)

(21) Appl. No.: 18/679,460

(22) Filed: May 31, 2024

(30) Foreign Application Priority Data
Jun. 1, 2023 (JP) 2023-091021

(51) Int. Cl. G09G 3/00; H10K 59/12; H10K 59/131

(52) U.S. Cl. CPC G09G 3/006; H10K 59/1201; H10K 59/131; G09G 2330/12

(57) ABSTRACT

According to one embodiment, a substrate includes a display area including a plurality of pixels, a surrounding area that surrounds the display area, and an inspection pad portion provided in the surrounding area, and the inspection pad portion includes a plurality of first pads and a plurality of second pads aligned in a first direction, a plurality of third pads aligned in the first direction, and arranged at positions displaced from the plurality of first pads in a second direction intersecting the first direction, and a plurality of first conductive lines connecting the plurality of first pads with the plurality of third pads, respectively.

### CROSS-REFERENCE TO RELATED APPLICATION

This application is based upon and claims the benefit of priority from Japanese Patent Application No. 2023-091021, filed Jun. 1, 2023, the entire contents of which are incorporated herein by reference.

### FIELD

Embodiments described herein relate generally to a substrate, a substrate inspection method, and a display device manufacturing method.

### BACKGROUND

In recent years, various forms of display devices have been proposed. In the manufacturing process of display devices, inspections are performed to check for short circuit or break between wires of the display device, and the like. In the inspection, a plurality of probes are applied to a plurality of pads formed on the display device, and inspection signals are supplied to the display device through the probes and the pads.

In contrast, the number and arrangement of pads are different depending on the product specifications. For this reason, probes of different configurations need to be prepared for each product, which may be a factor for increase in costs and reduction in inspection efficiency.

### BRIEF DESCRIPTION OF THE DRAWINGS

FIG. 1 is a diagram showing a configuration example of a display device.

FIG. 2 is a diagram showing an example of a layout of sub-pixels.

FIG. 3 is a schematic cross-sectional view showing the display device along line III-III in FIG. 2.

FIG. 4 is a flowchart illustrating an example of a method of manufacturing the display device.

FIG. 5 is a diagram illustrating a process of preparing a substrate.

FIG. 6 is a diagram showing a configuration example of a touch panel.

FIG. 7 is an enlarged diagram showing a configuration example of an inspection pad portion.

FIG. 8 is a diagram showing an example of an inspection device that performs inspection for a touch panel.

FIG. 9 is a schematic plan view showing an example of a configuration applicable to a head used for the inspection.

FIG. 10 is a schematic plan view showing a relationship between the pad shown in FIG. 7 and the probe shown in FIG. 9.

FIG. 11 is a schematic plan view showing another example of the configuration applicable to the display device.

FIG. 12 is a schematic plan view showing a relationship between the pad shown in FIG. 7 and the probe shown in FIG. 11.

FIG. 13 is a diagram illustrating a process of cutting the inspection pad portion.

### DETAILED DESCRIPTION

In general, according to one embodiment, a substrate comprises a display area including a plurality of pixels, a surrounding area that surrounds the display area, and an inspection pad portion provided in the surrounding area. The inspection pad portion comprises a plurality of first pads and a plurality of second pads aligned in a first direction, a plurality of third pads aligned in the first direction, and arranged at positions displaced from the plurality of first pads in a second direction intersecting the first direction, and a plurality of first conductive lines connecting the plurality of first pads with the plurality of third pads, respectively.

According to another embodiment, an inspection method comprises bringing a plurality of probes that a head comprises into contact with at least the plurality of first pads or the plurality of third pads, and the plurality of second pads, and inspecting the substrate by supplying inspection signals via the plurality of probes.

According to yet another embodiment, a display device manufacturing method comprises preparing the substrate, bringing a plurality of probes that a head comprises into contact with at least the plurality of first pads or the plurality of third pads, and the plurality of second pads, inspecting the substrate by supplying inspection signals via the plurality of probes, and cutting the inspection pad portion from the substrate.

According to each of the embodiments, a substrate, a substrate inspection method, and a display device manufacturing method, capable of reducing costs and improving inspection efficiency can be provided.

Embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. To more clarify the explanations, the drawings may pictorially show width, thickness, shape and the like of each portion as compared with actual embodiments, but they are mere examples and do not restrict the interpretation of the invention. Furthermore, in the description and figures of the present application, structural elements having the same or similar functions will be referred to by the same reference numbers and detailed explanations of them that are considered redundant may be omitted.

In the drawings, an X-axis, a Y-axis and a Z-axis orthogonal to each other are shown as needed in order to facilitate understanding. A direction along the X-axis is referred to as a first direction X, a direction along the Y-axis is referred to as a second direction Y, and a direction along the Z-axis is referred to as a third direction Z. Viewing various elements parallel to the third direction Z is referred to as plan view.

In the present embodiment, a display device comprising an organic light emitting diode (OLED) as a light emitting element is exemplified. However, the configuration of the display device is not limited to this. For example, the display device may be a liquid crystal display device with a liquid crystal layer or an LED display device with a light emitting diode (LED).

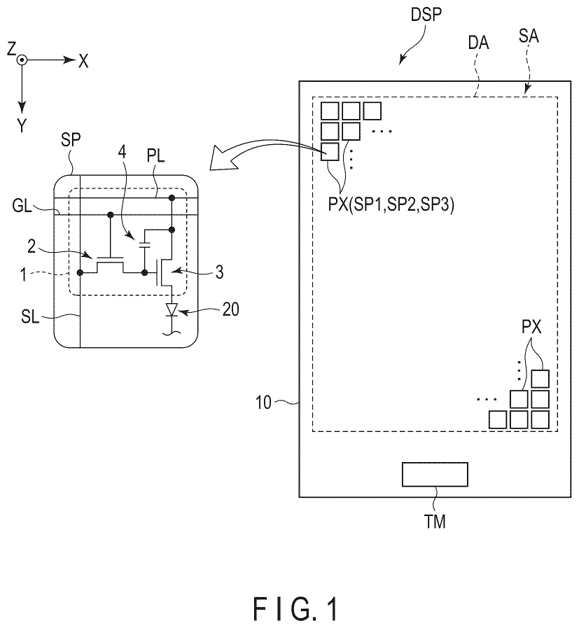

FIG. 1 is a diagram showing a configuration example of a display device DSP. The display device DSP has a display area DA where images are displayed and a surrounding area SA that surrounds the display area DA, on an insulating base 10. The base 10 may be glass or a flexible resin film. A touch panel including a plurality of touch electrodes is arranged on the display area DA, as described in detail below.

The display area DA includes a plurality of pixels PX arrayed in a matrix in the first direction X and the second direction Y. The pixel PX comprises a plurality of sub-pixels SP. In an example, the pixel PX comprises a red sub-pixel SP1, a green sub-pixel SP2, and a blue sub-pixel SP3. In addition to the sub-pixels of the above three colors, the pixel PX may comprise four or more sub-pixels including a sub-pixel of the other color such as white.

A terminal TM is provided in the surrounding area SA. For example, a flexible circuit board for supplying various signals to the display device DSP is connected to the terminal TM. An IC for driving may be mounted between the display area DA and the terminal TM.

The sub-pixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

At the pixel switch 2, a gate electrode is connected to a scanning line GL. Either of a source electrode and a drain electrode of the pixel switch 2 is connected to a signal line SL, and the other is connected to a gate electrode of the drive transistor 3, and the capacitor 4. In the example shown in FIG. 1, the scanning line GL extends in the first direction X and the signal line SL extends in the second direction Y. At the drive transistor 3, either of the source electrode and the drain electrode is connected to a power line PL and the capacitor 4, and the other is connected to an anode of a display element 20. Incidentally, the configuration of the pixel circuit 1 is not limited to the example shown in the figure.

The display element 20 is an organic light emitting diode (OLED) serving as a light emitting element. For example, the sub-pixel SP1 comprises a display element 20 that emits light corresponding to a red wavelength, the sub-pixel SP2 comprises a display element 20 that emits light corresponding to a green wavelength, and the sub-pixel SP3 comprises a display element 20 that emits light corresponding to a blue wavelength.

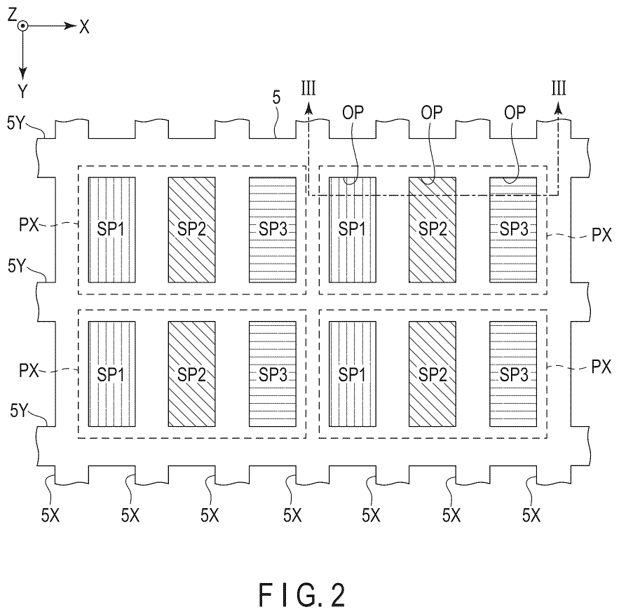

FIG. 2 is a diagram showing an example of a layout of the sub-pixels SP1, SP2, and SP3. Four pixels PX will be focused here. In each of the pixels PX, the sub-pixels SP1, SP2, and SP3 are aligned in this order in the first direction X. In other words, a column constituted by a plurality of sub-pixels SP1 aligned in the second direction Y, a column constituted by a plurality of sub-pixels SP2 aligned in the second direction Y, and a column constituted by a plurality of sub-pixels SP3 aligned in the second direction Y are alternately arranged in the first direction X, in the display area DA.

A rib 5 is arranged at boundaries of the sub-pixels SP1, SP2, and SP3. In the example shown in FIG. 2, the rib 5 has a grating shape having a plurality of ribs 5X located between the sub-pixels SP adjacent to each other in the first direction X and a plurality of ribs 5Y located between the sub-pixels SP adjacent to each other in the second direction Y. In the example shown in FIG. 2, the ribs 5X extend parallel to the second direction Y and the ribs 5Y extend parallel to the first direction X. An aperture OP is formed at each of the sub-pixels SP1, SP2, and SP3, by the ribs 5X and 5Y.

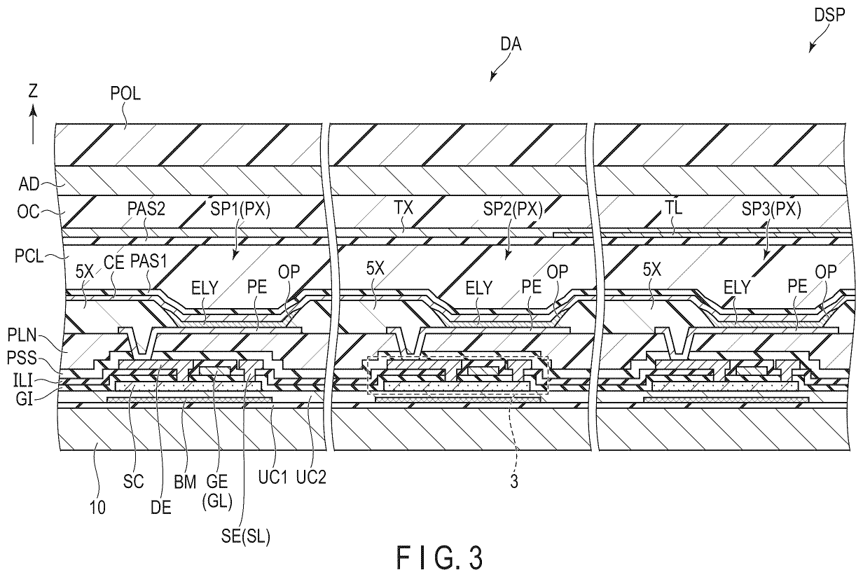

FIG. 3 is a schematic cross-sectional view showing the display device DSP along line III-III in FIG. 2. An insulating layer UC1 is provided on the base 10. A light-shielding layer BM which overlaps with the drive transistors 3 of the pixels PX may be provided on the insulating layer UC1. The light-shielding layer BM suppresses the change in transistor characteristics caused by entry of light from the channel back surfaces of the drive transistors 3, or the like. When the light-shielding layer BM is formed of a conductive layer, a back gate effect can be applied to the drive transistors 3 by applying a predetermined potential.

The insulating layer UC1 and the light-shielding layer BM are covered with an insulating layer UC2. The drive transistors 3 are provided on the insulating layer UC2. The drive transistor 3 includes a semiconductor layer SC, an insulating layer GI, a gate electrode GE (scanning line GL), an insulating layer ILI, a source electrode SE (signal line SL), and a drain electrode DE.

For the semiconductor layer SC, for example, amorphous silicon, polysilicon or an oxide semiconductor can be used. For the gate electrode GE, for example, molybdenum tungsten alloy (MoW) can be used. The gate electrode GE may be formed integrally with the scanning line GL. Each of the insulating layers UC1 and UC2, the insulating layer GI, and the insulating layer ILI can be formed as, for example, a single layer body of a silicon oxide film or silicon nitride film, or a stacked layer body of a silicon oxide film and a silicon nitride film.

The semiconductor layer SC is provided on the insulating layer UC2. The semiconductor layer SC is covered with the insulating layer GI. The gate electrode GE which overlaps with the semiconductor layer SC is provided on the insulating layer GI. The insulating layer GI and the gate electrode GE are covered with the insulating layer ILI. The source electrode SE and the drain electrode DE are provided on the insulating layer ILI. The source electrode SE and the drain electrode DE are connected to the source area and the drain area of the semiconductor layer SC, via contact holes provided in the insulating layer ILI and the insulating layer GI, respectively. The source electrode SE may be formed integrally with the signal line SL.

The source electrode SE, the drain electrode DE, and the insulating layer ILI are covered with an insulating layer PSS. The insulating layer PSS is covered with an insulating layer PLN. The insulating layer PSS is an inorganic layer formed of an inorganic insulating material. Examples of the inorganic insulating material include a single layer body of silicon oxide or silicon nitride, or a stacked layer body of silicon oxide and silicon nitride. The insulating layer PLN is an organic layer formed of an organic resin material. Examples of the organic resin material include photosensitive acrylic, polyimide, and the like. The insulating layer PLN has a function of planarizing the unevenness caused by the drive transistors 3.

Pixel electrodes PE are provided on the insulating layer PLN. The pixel electrodes PE are connected to the drain electrodes DE via contact holes provided in the insulating layer PSS and the insulating layer PLN. The pixel electrode PE includes, for example, a reflective layer and a pair of protective layers that cover an upper surface and a lower surface of the reflective layer. For the reflective layer, for example, silver (Ag) can be used. For the pair of protective layers, for example, a transparent conductive material such as indium tin oxide (ITO) or indium zinc oxide (IZO) can be used.

The rib 5X is provided between adjacent pixel electrodes PE. The aperture OP that exposes a part the pixel electrode PE is formed by the rib 5X. An organic layer ELY which overlaps with the pixel electrode PE is provided between adjacent ribs 5X. The organic layer ELY includes a light emitting layer composed of an organic EL material. Furthermore, the organic layer ELY may include a hole-injection layer, a hole-transport layer, an electron blocking layer, a hole blocking layer, an electron-transport layer, and an electron-injection layer.

The common electrode CE is provided on the organic layer ELY. The common electrode CE is a conductive thin film through which the light emitted from the organic layer ELY can be transmitted. For example, a magnesium-silver alloy (MgAg) can be used as the material of the common electrode CE, but the material is not limited to this. In the present embodiment, the pixel electrode PE serves as an anode, and the common electrode CE serves as a cathode. The light emitted from the organic layer ELY is extracted from the upper side via the common electrode CE. In other words, the display device DSP has a top-emission structure.

The common electrode CE is covered with an insulating layer PAS1. The insulating layer PAS1 comprises a function of preventing entry of water from the outside into the organic layer ELY. A material having a high gas barrier property is suitable for the insulating layer PAS1. The insulating layer PAS1 is an inorganic layer formed of an inorganic insulating material. Examples of the inorganic insulating material include a single layer body of silicon oxide or silicon nitride, or a stacked layer body of silicon oxide and silicon nitride.

The insulating layer PAS1 is covered with an insulating layer PCL. The insulating layer PCL has a planarizing function. The insulating layer PCL is formed of an organic resin material. Examples of the organic resin material include photosensitive acrylic and polyimide.

An insulating layer PAS2 is provided on the insulating layer PCL. The insulating layer PAS2 can be formed of the same material as the insulating layer PAS1. A conductive line TL is provided on the insulating layer PAS2. The insulating layer PAS2 and the conductive line TL are covered with a touch electrode TX. The touch electrode TX can be formed of, for example, a transparent conductive material such as ITO or IZO. As another example, the touch electrode TX may be formed of a thin metal wire.

An insulating layer OC is provided on the touch electrode TX. The insulating layer OC is formed of a resin material having translucency. In the example of FIG. 3, a polarizer POL is attached to the insulating layer OC via an adhesive layer AD. For the adhesive layer AD, an optical clear adhesive (OCA) can be used.

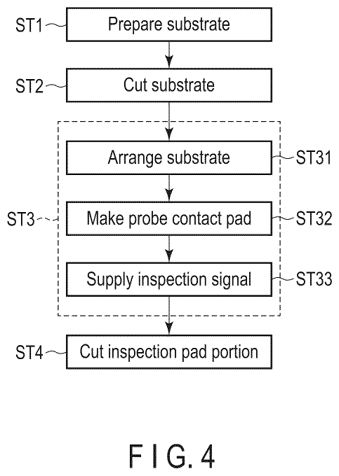

Next, an example of a method of manufacturing the display device DSP will be described with reference to FIG. 4 to FIG. 13.

FIG. 4 is a flowchart illustrating an example of the method of manufacturing the display device DSP. The manufacturing method described here substantially includes a process of preparing a motherboard MB (step ST1), a process of cutting the motherboard MB (step ST2), a process of inspecting a substrate SUB cut from the motherboard MB (step ST3), and a process of cutting inspection pad portions PD1 and PD2 provided on the substrate SUB (step ST4).

Steps ST1 to ST4 will be specifically described below.

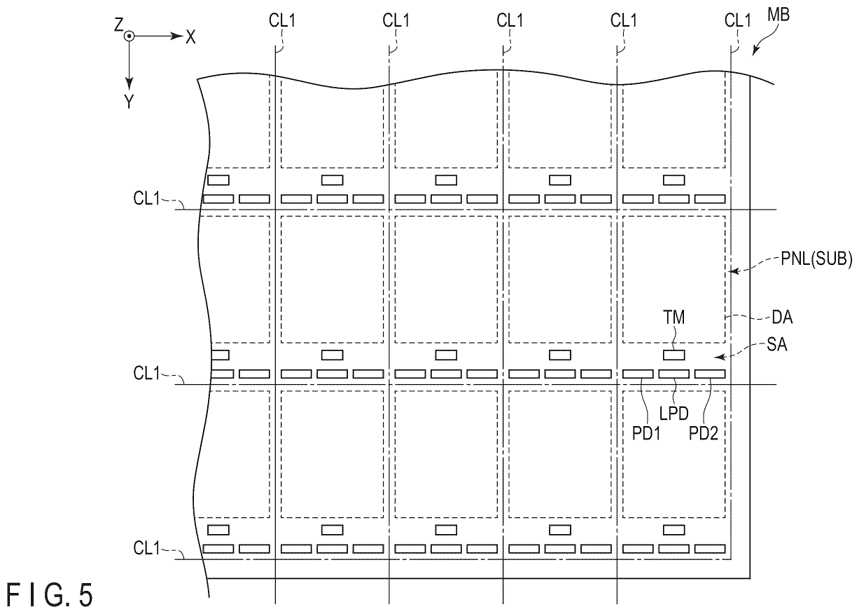

First, in step ST1, for example, the motherboard MB having the configuration shown in FIG. 5 is prepared. The motherboard MB comprises a plurality of panel portions PNL arranged in the first direction X and the second direction Y. In the example shown in FIG. 5, the plurality of panel portions PNL are adjacent to each other in the first direction X and the second direction Y, but a gap may be provided between the panel portions PNL.

The panel portion PNL has a display area DA and a surrounding area SA that surrounds the display area DA. The surrounding area SA has a terminal TM, inspection pad portions PD1 and PD2, and a lighting inspection pad portion LPD. The inspection pad portions PD1 and PD2 and the lighting inspection pad portion LPD are aligned in the first direction X. The lighting inspection pad portion LPD is arranged between the inspection pad portions PD1 and PD2. The terminal TM is arranged between the display area DA and the lighting inspection pad portion LPD. As described in detail below, the inspection pad portions PD1 and PD2 are used to inspect short circuit, break, and the like of the touch electrode, conducive lines, and the like of the touch panel. The lighting inspection pad portion LPD is used to inspect whether or not each pixel PX of the display device DSP is normally turned on, and the like.

Incidentally, the configuration of the panel portion PNL is not limited to the example shown in the figure. For example, the panel portion PNL may include only one inspection pad portion for inspection related to the touch panel or may include three or more inspection pad portions.

In step ST2 shown in FIG. 4, the motherboard MB is cut along cut lines CL1 shown in FIG. 5. The cut lines CL1 are set between adjacent panel portions PNL along the first direction X and the second direction Y.

In the following description, the panel portion PNL cut from the motherboard MB along the cut lines CL1 is referred to as the substrate SUB.

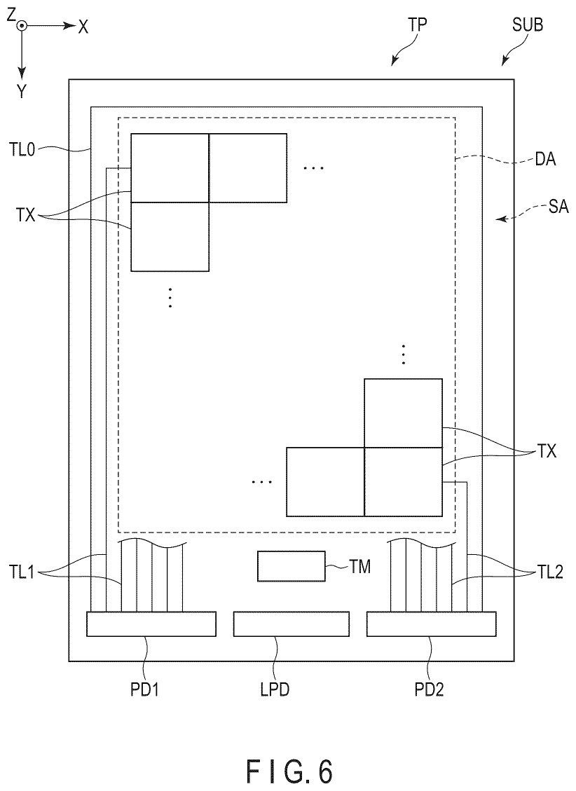

FIG. 6 is a diagram showing a configuration example of the touch panel TP. The touch panel TP has a plurality of touch electrodes TX arranged in the display area DA. In the example shown in FIG. 6, a plurality of rectangular-shaped touch electrodes TX are arranged along the first direction X and the second direction Y. However, the shape and arrangement of the touch electrodes TX are not limited to this example.

The substrate SUB includes a conductive lines TL0 and a plurality of conductive lines TL1 and TL2 (second conductive lines). The plurality of conductive lines TL1 connect parts of the plurality of touch electrodes TX with the inspection pad portion PD1. The plurality of conductive lines TL2 connect the remaining parts of the plurality of touch electrodes TX with the inspection pad portion PD2. A conductive line TL0 is drawn around the display area DA and connected to both of the inspection pad portions PD1 and PD2. The plurality of touch electrodes TX may be connected to one conductive line TL1.

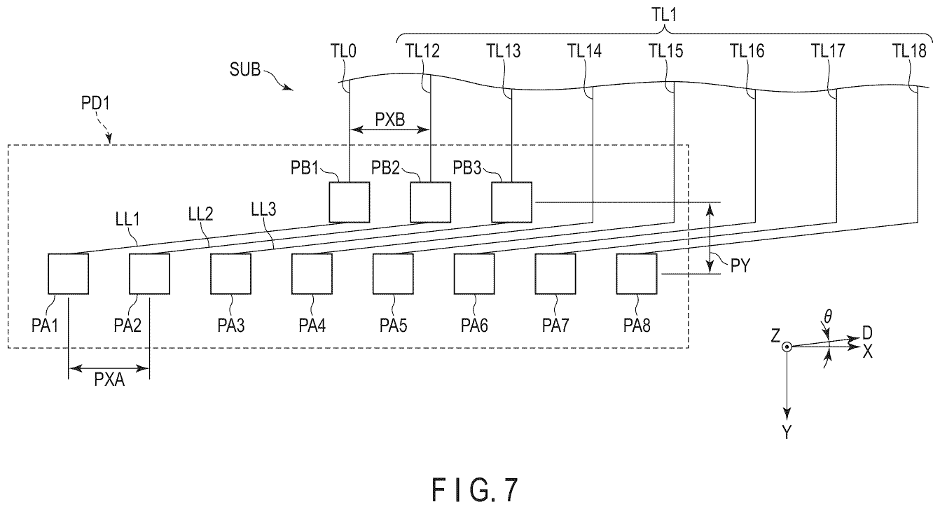

FIG. 7 is an enlarged view showing a configuration example of the inspection pad portion PD1. Incidentally, the inspection pad portion PD2 in FIG. 6 has a shape symmetrical to the inspection pad portion PD1 shown in FIG. 7 with respect to the axis along the second direction Y.

The inspection pad portion PD1 comprises pads PA1 to PA8 and PB1 to PB3 and conductive lines LL1 to LL3 (first conductive lines). In the present embodiment, each of the pads PA1 to PA8 and PB1 to PB3 is formed in a square shape. However, the shape of the pads PA1 to PA8 and PB1 to PB3 is not limited to this example. The pads PA1 to PA3 are examples of a first pad, the pads PA4 to PA8 are examples of a second pad, and the pads PB1 to PB3 are examples of a third pad.

The pads PA1 to PA8 are aligned at regular intervals at a pitch PXA (first and second pitches) along the first direction X. The pads PB1 to PB3 are arranged at positions displaced from the pads PA1 to PA8 in the second direction Y. More specifically, the pads PB1 to PB3 are located between the pads PA1 to PA8 and the display area DA shown in FIG. 6. The pads PB1 to PB3 are aligned at a pitch PY (seventh pitch) with respect to the pads PA1 to PA8. The pads PB1 to PB3 are aligned at regular intervals at a pitch PXB (third pitch) along the first direction X. The pad PB1 is arranged between the pads PA4 and PAS adjacent in the first direction X. The pad PB2 is arranged between the pads PAS and PA6 adjacent in the first direction X. The pad PB3 is arranged between the pads PA6 and PA7 adjacent in the first direction X.

Incidentally, the pitch PXA corresponds to an interval along the first direction X between centers of two adjacent pads among the pads PA1 to PA8. The pitch PXB corresponds to an interval along the first direction X between centers of two adjacent pads among the pads PB1 to PB3. The pitch PY corresponds to an interval along the second direction Y between the centers of the pads PA1 to PA8 and the centers of the pads PB1 to PB3. In the example shown in FIG. 7, the pitches PXA and PXB are equal to each other.

The conductive line LL1 extends in a fourth direction D and connects the pad PA1 with the pad PB1. The conductive line LL2 extends in the fourth direction D and connects the pad PA2 with the pad PB2. The conductive line LL3 extends in the fourth direction D and connects the pad PA3 with the pad PB3. Incidentally, the fourth direction D is a direction which intersects the first direction X and the second direction Y. The fourth direction D is inclined at an angle e, which is an acute angle to the first direction X.

In the example shown in FIG. 7, one conductive line TL0 and seven conductive lines TL1 (TL12 to TL18) are arranged. The conductive line TL0 extends in the second direction Y and is connected to the pad PB1. The conductive line TL12 extends in the second direction Y and is connected to the pad PB2. The conductive line TL13 extends in the second direction Y and is connected to the pad PB3. The conductive line TL14 extends in the second direction Y, is bent in the middle, extends in the fourth direction D, and is connected to the pad PA4. The conductive line TL15 extends in the second direction Y, is bent in the middle, extends in the fourth direction D, and is connected to the pad PA5. The conductive line TL16 extends in the second direction Y, is bent in the middle, extends in the fourth direction D, and is connected to the pad PA6. The conductive line TL17 extends in the second direction Y, is bent in the middle, extends in the fourth direction D, and is connected to the pad PA7. The conductive line TL18 extends in the second direction Y, is bent in the middle, extends in the fourth direction D, and is connected to the pad PA8.

For example, portions parallel to the second direction Y, among the conductive lines TL0, TL12, and TL13 and the conductive lines TL14 to TL18, are aligned at regular intervals in the first direction X. In addition, portions parallel to the fourth direction D, among the conductive lines LL1 to LL3 and the conductive lines TL14 to TL18, are aligned at regular intervals in the first direction X.

Next, the process of step ST3 in FIG. 4 will be described. This process includes inspection related to the touch panel using the inspection pad portions PD1 and PD2 and inspection related to the display using the lighting inspection pad portion LPD. The inspection related to the touch panel is performed by, for example, the process of steps ST31 to ST33 shown in FIG. 4.

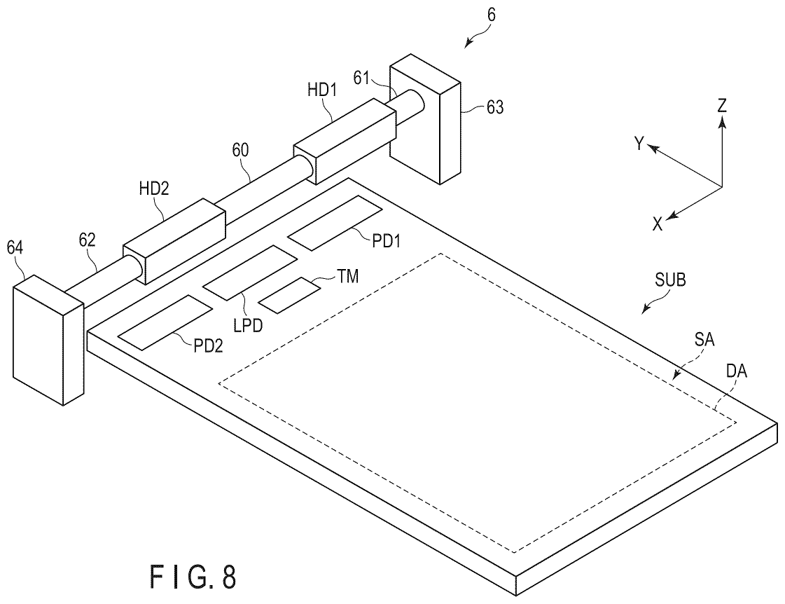

FIG. 8 is a diagram showing an example of an inspection device 6 that performs the inspection related to the touch panel on the substrate SUB. The inspection device 6 comprises heads HD1 and HD2. In step ST31 of FIG. 4, the substrate SUB is arranged under the heads HD1 and HD2 such that the inspection pad portions PD1 and PD2 are opposed to the heads HD1 and HD2, respectively, as shown in FIG. 8. In the subsequent process of step ST32, the inspection device 6 lowers the heads HD1 and HD2 toward the substrate SUB. Furthermore, in the process of step ST33, the inspection device 6 inspects the substrate SUB by supplying inspection signals to the substrate SUB through the heads HD1 and HD2. Details of the structure of the inspection system 6 and the inspection process will be described below using the first direction X, second direction Y and third direction Z, assuming that the substrate SUB is arranged under the heads HD1 and HD2 as shown in FIG. 8.

The heads HD1 and HD2 are formed in a rectangular shape extending in the first direction X. Probes are formed on the surfaces of the heads HD1 and HD2, which are opposed to the inspection pad portions PD1 and PD2, respectively. The probes extend along the third direction Z toward the substrate SUB. Details of the probes will be described below.

The inspection device 6 further comprises support members 60, 61, and 62 and elevating mechanisms 63 and 64. The support members 60, 61, and 62 are formed in, for example, a cylindrical shape extending in the first direction X. An end of the support member 60 is connected to the head HD1, and the other end of the support member 60 is connected to the head HD2. An end of the support member 61 is connected to the head HD1, and the other end of the support member 61 is connected to an elevating mechanism 63. An end of the support member 62 is connected to the head HD2, and the other end of the support member 62 is connected to an elevating mechanism 64. The elevating mechanisms 63 and 64 move the support members 61 and 62 parallel to the third direction Z. Therefore, the heads HD1 and HD2 can be moved parallel to the third direction Z, and the probes provided at the heads HD1 and HD2 can be brought into contact with and separated from the inspection pad portions PD1 and PD2, respectively.

Incidentally, the configuration of the inspection device 6 is not limited to the example shown in the figure. For example, the number of heads may be increased or decreased in accordance with the number of inspection pad portions provided on the substrate SUB.

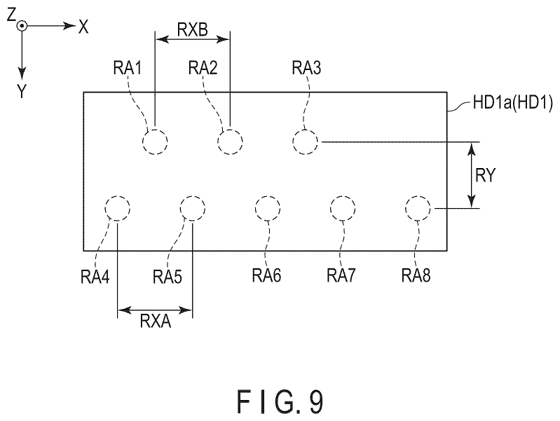

FIG. 9 is a schematic plan view showing an example of the configuration applicable to the head HD1. The head HD1 shown in this figure is hereinafter referred to as a head HD1a. Incidentally, a head having a shape symmetrical to the head HD1a shown in FIG. 9 with respect to the axis along the second direction Y can be used as the head HD2 in FIG. 8.

The head HD1a comprises probes RA1 to RA8. In FIG. 9, the planar shape of the probes RA1 to RA8 is a circular shape, but is not limited to this. For example, the planar shape of the probes RA1 to RA8 may be a rectangular shape.

The probes RA4 to RA8 (first probes) are aligned at regular intervals at a pitch RXA (fifth pitch) along the first direction X. The probes RA1 to RA3 (second probes) are arranged at positions displaced from the probes RA4 to RA8 in the second direction Y. The probes RA to RA3 are aligned with the probes RA4 to RA8 at a pitch RY (eighth pitch). The probes RA1 to RA3 are aligned at regular intervals at a pitch RXB (sixth pitch) along the first direction X. The probe RA1 is arranged between the adjacent probes RA4 and RA5 in the first direction X. The probe RA2 is arranged between the adjacent probes RA5 and RA6 in the first direction X. The probe RA3 is arranged between the adjacent probes RA6 and RA7 in the first direction X.

Incidentally, the pitch RXA corresponds to an interval along the first direction X between the centers of two adjacent probes among the probes RA4 to RA8. The pitch RXB corresponds to an interval along the first direction X between the centers of two adjacent probes among the probes RA1 to RA3. The pitch RY corresponds to an interval along the second direction Y between the centers of the probes RA1 to RA3 and the centers of the probes RA4 to RA8. In the example shown in FIG. 9, the pitches RXA and RXB are equal to each other. In addition, the pitch RXA is equal to the pitch PXA shown in FIG. 7, the pitch RXB is equal to the pitch PXB shown in FIG. 7, and the pitch RY is equal to the pitch PY shown in FIG. 7.

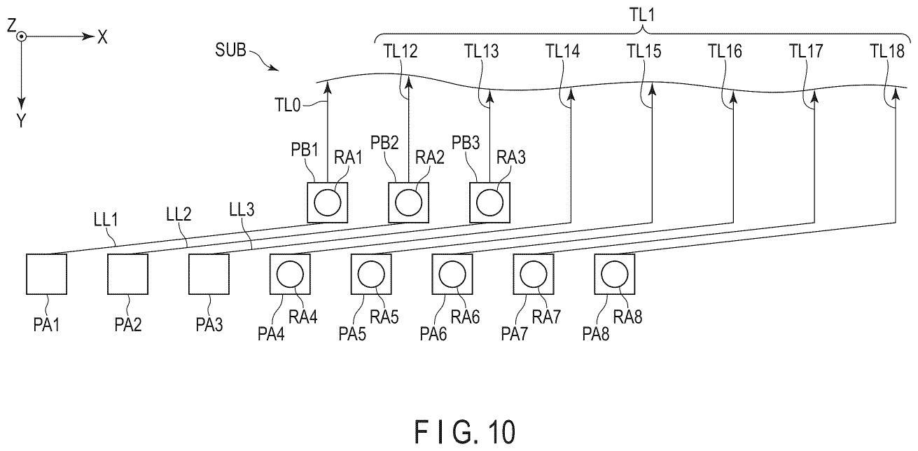

FIG. 10 is a schematic plan view showing a relationship between the pads PA1 to PA8 and PB1 to PB3 shown in FIG. 7 and the probes RA1 to RA8 shown in FIG. 9. When the head HD1a is lowered toward the substrate SUB in the process of step ST32, the probes RA1 to RA3 contact the pads PB1 to PB3 of the inspection pad portion PD1, respectively. Furthermore, the probes RA4 to RA8 contact the pads PA4 to PA8 of the inspection pad portion PD1, respectively. The probes RA1 to RA8 do not contact the pads PA1 to PA3.

When the same structure as that of the head HD1a is applied to the head HD2, the relationship in contact between the probes of the head HD2 and the pads of the inspection pad portion PD2 is the same as that between the probes RA1 to RA8 and the pads PA1 to PA8 and PB1 to PB3 shown in FIG. 10.

When the process of step ST33 is performed using the head HD1a, the inspection device 6 supplies inspection signals to each of the probes RA1 to RA8. The inspection signal supplied to the probe RA1 is supplied to the conductive line TL0 through the pad PB1. The inspection signal supplied to the probe RA2 is supplied to the conductive line TL12 through the pad PB2. The inspection signal supplied to the probe RA3 is supplied to the conductive line TL13 through the pad PB3. The inspection signal supplied to the probe RA4 is supplied to the conductive line TL14 through the pad PA4. The inspection signal supplied to the probe RA5 is supplied to the conductive line TL15 through the pad PA5. The inspection signal supplied to the probe RA6 is supplied to the conductive line TL16 through the pad PA6. The inspection signal supplied to the probe RA7 is supplied to the conductive line TL17 through the pad PA7. The inspection signal supplied to the probe RA8 is supplied to the conductive line TL18 through the pad PA8.

Examples of the inspection performed in step ST33 include inspection of a short circuit between adjacent touch electrodes TX, inspection of a disconnection of the conductive line TL0, and the like. For example, in the inspection of short circuit, inspection signals are supplied to the probes RA1 to RA8 of the head HD1a and the probe of the head HD2 in time division. Furthermore, the voltage of each probe is detected when each inspection signal is supplied. When an inspection signal supplied to one of the probes is detected as the voltage of the other probe, the touch electrode TX connected to these probes may be short-circuited.

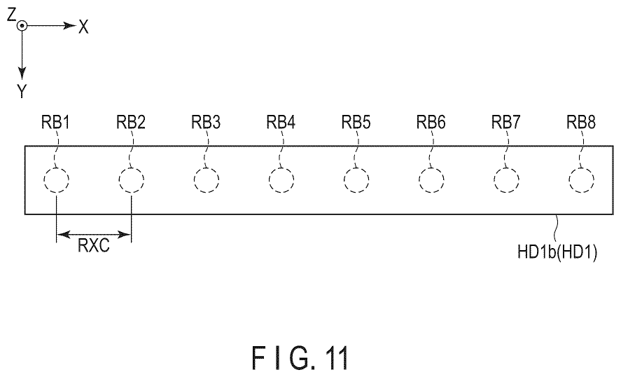

FIG. 11 is a schematic plan view showing another example of the configuration applicable to the head HD1. The head HD1 shown in this figure is hereinafter referred to as a head HD1b. Incidentally, a head having a shape symmetrical to the head HD1b shown in FIG. 11 with respect to the axis along the second direction Y can be used as the head HD2 in FIG. 8.

The head HD1b comprises probes RB1 to RB8. In FIG. 9, the planar shape of the probes RA1 to RA8 is a circular shape, but is not limited to this. For example, the planar shape of the probes RB1 to RB8 may be a rectangular shape.

The probes RB1 to RB8 are aligned at regular intervals at a pitch RXC (fourth pitch) along the first direction X. Incidentally, the pitch RXC corresponds to an interval along the first direction X between the centers of two adjacent probes among the probes RB1 to RB8. In addition, the pitch RXC is equal to the pitch PXA shown in FIG. 7.

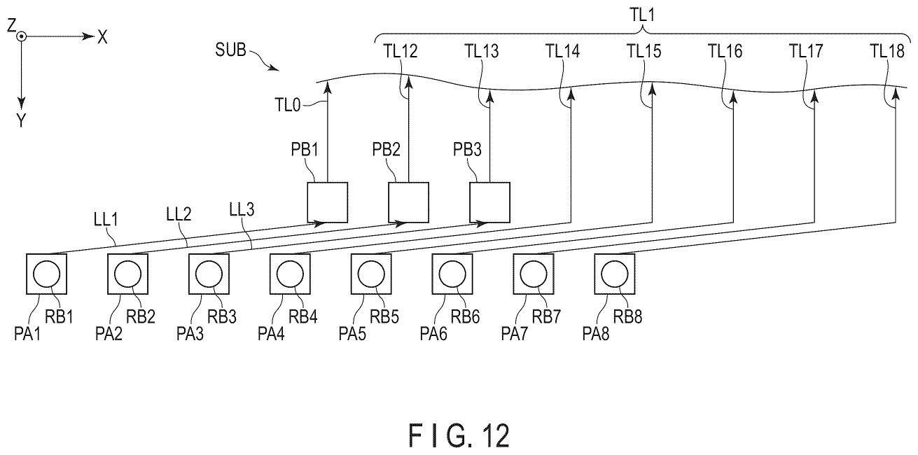

FIG. 12 is a schematic plan view showing a relationship between the pads PA1 to PA8 and PB1 to PB3 shown in FIG. 7 and the probes RB1 to RB8 shown in FIG. 11. When the head HD1b is lowered toward the substrate SUB in the process of step ST32, the probes RB1 to RB8 contact the pads PA1 to PA8 of the inspection pad portion PD1, respectively. The probes RB1 to RB8 do not contact the pads PB1 to PB3.

When the same structure as that of the head HD1b is applied to the head HD2, the relationship in contact between the probes of the head HD2 and the pads of the inspection pad portion PD2 is the same as that between the probes RB1 to RB8 and the pads PA1 to PA8 and PB1 to PB3 shown in FIG. 12.

When the process of step ST33 is performed using the head HD1b, the inspection device 6 supplies inspection signals to each of the probes RB1 to RB8. The inspection signal supplied to the probe RB1 is supplied to the conductive line TL0 through the pad PA1, the conductive line LL1, and the pad PB1. The inspection signal supplied to the probe RB2 is supplied to the conductive line TL12 through the pad PA2, the conductive line LL2, and the pad PB2. The inspection signal supplied to the probe RB3 is supplied to the conductive line TL13 through the pad PA3, the conductive line LL3, and the pad PB3. The inspection signal supplied to the probe RB4 is supplied to the conductive line TL14 through the pad PA4. The inspection signal supplied to the probe RB5 is supplied to the conductive line TL15 through the pad PA5. The inspection signal supplied to the probe RB6 is supplied to the conductive line TL16 through the pad PA6. The inspection signal supplied to the probe RB7 is supplied to the conductive line TL17 through the pad PA7. The inspection signal supplied to the probe RB8 is supplied to the conductive line TL18 through the pad PA8. In the case of using the head HD1b as well, inspection of the short circuit of the touch electrode TX, inspection of the disconnection of the conductive line TL0, and the like as described above can be performed.

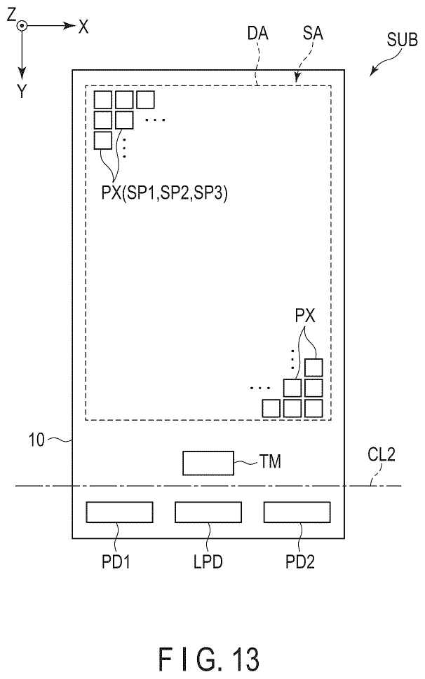

Next, the process of step ST4 in FIG. 4 will be described. FIG. 13 is a diagram illustrating a process of cutting the inspection pad portions PD1 and PD2. In step ST4, the substrate SUB is cut along cut lines CL2 shown in FIG. 13. The cut line CL2 is parallel to, for example, the first direction X and is set between the inspection pad portions PD1 and PD2 and the lighting inspection pad portion LPD, and the terminal TM, in the second direction Y. By cutting the substrate SUB along the cut line CL2, the inspection pad portions PD1 and PD2 and the lighting inspection pad portion LPD are removed from the substrate SUB. The substrate that remains as a result is the display device DSP shown in FIG. 1.

In the above processes, the operations of the substrate SUB are inspected, and the display device DSP is manufactured.

According to the present embodiment, the pads PA1 to PA3 (first pads) and the pads PB1 to PB3 (third pads) are connected by the conductive lines LL1 to LL3, respectively, as shown in FIG. 7. Therefore, the inspection signals can be supplied to the substrate SUB by making the probe contact at least either the pads PA1 to PA3 or the pads PB1 to PB3. Therefore, the head HD1a in which the probes are aligned in two rows in the second direction Y as shown in FIG. 9 can be used, and the head HD1b in which the probes are aligned in one row as shown in FIG. 11 can be used. Thus, since a plurality of heads are available for one type of pad arrangement, the availability of existing heads is increased. When existing heads are available, costs can be reduced since there is no need to design and manufacture new heads. In addition, since a plurality of heads are available, work to replace heads each time product specifications change can be saved, and the inspection efficiency can be improved.

In the head HD1, it is necessary to maintain a certain distance between probes in close proximity. In this regard, the pads PB1 to PB3 and the pads PA1 to PA8 are displaced in the first direction X, in the example shown in FIG. 10. Similarly, the probes RA1 to RA3 and the probes RA4 to RA8 are displaced in the first direction X. In this configuration, the distance between the probes RA1 to RA3 and the RA4 to RA8 can be maintained to be larger than that in a case where the probes RA1 to RA3 and the probes RA4 to RA8 are not displaced in the first direction X. As a result, the head HD1 and the inspection pad portion PD1 can be made more compact while maintaining a certain distance between the probes in close proximity. When the configuration of FIG. 10 is applied to the head HD2 and the inspection pad portion PD2, the same advantage can be obtained for the head HD2 and the inspection pad portion PD2.

All of the substrates, substrate inspection methods, and display device manufacturing methods that can be implemented by a person of ordinary skill in the art through arbitrary design changes to the substrates, substrate inspection methods, and display device manufacturing methods described above as embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A substrate comprising:
a display area including a plurality of pixels;
a surrounding area that surrounds the display area; and
an inspection pad portion provided in the surrounding area, wherein
the inspection pad portion comprises:
a plurality of first pads and a plurality of second pads aligned in a first direction;
a plurality of third pads aligned in the first direction, and arranged at positions displaced from the plurality of first pads in a second direction intersecting the first direction; and
a plurality of first conductive lines connecting the plurality of first pads with the plurality of third pads, respectively.

2. The substrate of claim 1, comprising:
a plurality of panel portions including the display area and the inspection pad portion.

3. The substrate of claim 1, further comprising:
a plurality of touch electrodes that overlap with the display area; and
a plurality of second conductive lines connecting the plurality of touch electrodes with the plurality of second pads and the plurality of third pads, respectively.

4. The substrate of claim 1, wherein
the plurality of first conductive lines extend in a direction intersecting the first direction and the second direction.

5. The substrate of claim 1, wherein
the plurality of third pads are located between the plurality of first pads and the display area in the second direction.

6. The substrate of claim 1, wherein
each of the plurality of third pads is arranged between the adjacent second pads in the first direction.

7. The substrate of claim 1, wherein
the plurality of first pads are aligned at regular intervals at a first pitch in the first direction,
the plurality of second pads are aligned at regular intervals at a second pitch in the first direction, and
the plurality of third pads are aligned at regular intervals at a third pitch in the first direction.

8. The substrate of claim 7, wherein
the first pitch, the second pitch, and the third pitch are equal to each other.

9. An inspection method of inspecting a substrate using a head comprising a plurality of probes,
the substrate comprising a display area including a plurality of pixels, a surrounding area that surrounds the display area, and an inspection pad portion provided in the surrounding area, wherein the inspection pad portion comprises a plurality of first pads and a plurality of second pads aligned in a first direction, a plurality of third pads aligned in the first direction, and arranged at positions displaced from the plurality of first pads in a second direction intersecting the first direction, and a plurality of first conductive lines connecting the plurality of first pads with the plurality of third pads, respectively,
the inspection method comprising:
bringing the plurality of probes into contact with at least the plurality of first pads or the plurality of third pads, and the plurality of second pads; and
inspecting the substrate by supplying inspection signals via the plurality of probes.

10. The inspection method of claim 9, wherein
the plurality of probes are aligned in the first direction, and
the plurality of probes are brought into contact with the plurality of first pads and the plurality of second pads.

11. The inspection method of claim 10, wherein
the plurality of probes are aligned at regular intervals at a fourth pitch in the first direction.

12. The inspection method of claim 1, wherein
the plurality of first pads are aligned at regular intervals at a first pitch in the first direction,
the plurality of second pads are aligned at regular intervals at a second pitch in the first direction, and
the first pitch, the second pitch, and the fourth pitch are equal to each other.

13. The inspection method of claim 9, wherein
the plurality of probes include a plurality of first probes aligned in the first direction, and a plurality of second probes aligned in the first direction and arranged at positions displaced from the plurality of first probes in the second direction, and
the plurality of first probes are brought into contact with the plurality of second pads, and the plurality of second probes are brought into contact with the plurality of third pads.

14. The inspection method of claim 13, wherein
the plurality of first probes are aligned at regular intervals at a fifth pitch in the first direction, and
the plurality of second probes are aligned at regular intervals at a sixth pitch in the first direction.

15. The inspection method of claim 14, wherein
the plurality of second pads are aligned at regular intervals at a second pitch in the first direction, and
the plurality of third pads are aligned at regular intervals at a third pitch in the first direction,
the second pitch and the fifth pitch are equal to each other, and
the third pitch and the sixth pitch are equal to each other.

16. The inspection method of claim 15, wherein
the second pitch, the third pitch, the fifth pitch, and the sixth pitch are equal to each other.

17. The inspection method of claim 13, wherein
the plurality of third pads are aligned in the second direction at a seventh pitch for the plurality of first pads and the plurality of second pads, and
the plurality of second probes are aligned in the second direction at an eighth pitch for the plurality of first probes, and
the seventh pitch and the eighth pitch are equal to each other.

18. A display device manufacturing method, comprising:
preparing a substrate comprising a display area including a plurality of pixels, a surrounding area that surrounds the display area, and an inspection pad portion provided in the surrounding area, wherein the inspection pad portion comprises a plurality of first pads and a plurality of second pads aligned in a first direction, a plurality of third pads aligned in the first direction, and arranged at positions displaced from the plurality of first pads in a second direction intersecting the first direction, and a plurality of first conductive lines connecting the plurality of first pads with the plurality of third pads, respectively;
bringing the plurality of probes that a head comprises into contact with at least the plurality of first pads or the plurality of third pads, and the plurality of second pads;
inspecting the substrate by supplying inspection signals via the plurality of probes; and
cutting the inspection pad portion from the substrate.

19. The display device manufacturing method of claim 18, wherein
in cutting the inspection pad portion from the substrate, the inspection pad portion is removed from the substrate by cutting a part between the display area and the inspection pad portion.

20. The display device manufacturing method of claim 19, wherein
the substrate further comprises a terminal located between the inspection pad portion and the display area in the second direction, and
in cutting the inspection pad portion from the substrate, the inspection pad portion is removed from the substrate by cutting a part between the terminal and the inspection pad portion.
